(19) United States
(12) Patent Application Publication
(10) Pub. No.: US 2021/0267099 A1
(43) Pub. Date: Aug. 26, 2021

(54) VORTEX COOLING TUNNEL IN VARIABLE FREQUENCY DRIVE

(71) Applicant: North American Electric, Inc., Hernando, MS (US)

(72) Inventor: Richard A. Cornutt, Southaven, MS (US)

(73) Assignee: North American Electric, Inc., Hernando, MS (US)

(21) Appl. No.: 17/182,225

(22) Filed: Feb. 22, 2021

Related U.S. Application Data
(60) Provisional application No. 62/979,689, filed on Feb. 21, 2020.

(51) Int. Cl. H05K 7/20; F25B 49/02

(52) U.S. Cl. CPC H05K 7/20918; F25B 2600/021; F25B 49/025

(57) ABSTRACT

Embodiments of a variable frequency drive (VFD) apparatus are disclosed. In an embodiment, the VFD apparatus includes an enclosure and one or more internal components housed in a first portion of the enclosure. Further, the VFD apparatus includes a compartment housed in a second portion of the enclosure. In an embodiment, the compartment includes an ingress for facilitating entry of air into the compartment and an egress for facilitating an exit of the entered air from the compartment. The first portion of the enclosure is isolated from the second portion of the enclosure.

### CROSS REFERENCE TO RELATED APPLICATIONS

This application claims the benefit of U.S. Provisional Patent Application Ser. No. 62/979,689, titled “Vortex Cooling Tunnel (VCT)”, filed Feb. 21, 2021, expressly incorporated by reference herein.

### FIELD OF THE INVENTION

The present invention is generally directed towards cooling variable frequency drive (VFD) and more specifically towards a Vortex Cooling Tunnel (VCT) for cooling the VFDs.

### BACKGROUND OF THE INVENTION

VFDs are typically used to adjust the frequency of an electric motor such that the electric motor can function at variable frequencies. However, the operation of a VFD may cause it to heat up because of both internal and environmental factors. Traditional methods for cooling VFDs include: (a) forced air cooling using external fans, (b) air conditioning, and/or (c) isolation of the VFD and other internal components in an environmentally controlled space (e-house).

High frequency power electronics used to create pulse-width modulation (PWM) wave forms in VFDs create heat which must be constantly managed to prevent overheating of the VFDs electronic components and in the case of a VFD package, overheating of other panel mounted components. The installation and environmental factors must be considered along with external sources of heat, that is, either they should be removed or managed appropriately. For instance, an important external consideration may be the effect of direct sunlight in which, practical precautions should be taken to remove the harmful effects by providing adequate shelter to the VFD.

Existing methods for VFD cooling face several challenges and there is no single method that provides all of the characteristics customers may desire for in a VFD package.

### SUMMARY OF THE INVENTION

Excessive watt loss of Variable Frequency Drives (VFDs) causes internal cooling problems in enclosed drives requiring external cooling methods. This requires fans which pull air from outside of the panel exposing the internal components of the VFD package to contaminants. The VCT, in accordance with the embodiments of this disclosure, isolates the watt loss from the internal components of the drive package and therefore, removes the heat from the internal components and eliminates the need for external cooling. This results in the drive cooling itself (no external fans required) and eliminates contaminants from getting inside the enclosure where the components are located.

In accordance with the embodiments of this disclosure, a VFD apparatus is disclosed. The VFD apparatus comprises an enclosure, a first portion, and a second portion. The first and second portions may be housed within the enclosure. The first portion of the VFD apparatus comprises one or more internal electronic components. The first portion may additionally comprise circuitry between these components along with the components themselves. The second portion comprises a compartment such as a VCT, the details of which, are described later in this disclosure. The compartment has an ingress for causing external air to enter the compartment and an egress for causing the air to exit the compartment and subsequently, flow over one or more heat sinks of the VFD. The VFD enclosure further comprises an exhaust mechanism to facilitate the exit of the air flowing through the one or more heat sinks. The heat sinks are disposed in such a manner that the exited air flows over the one or more heat sinks.

In further accordance with the embodiments of this disclosure, a method for cooling the VFD, is disclosed herein. The method comprises facilitating an inflow of air, through an ingress, into a compartment (e.g., the VCT) housed in a second portion of an enclosure of the VFD. The method further comprises traversing the entered air through the compartment to facilitate an exit of the air through an egress; wherein the traversed air is isolated from one or more internal components housed in a first portion of the enclosure. The method further comprises facilitating the flow of the exited air over one or more heat sinks housed in the enclosure and subsequently, facilitating the exit of the air flowing through the one or more heat sinks through an exhaust mechanism.

### BRIEF DESCRIPTION OF THE DRAWINGS

Further advantages of the invention will become apparent by reference to the detailed description of preferred embodiments when considered in conjunction with the drawings:

FIG. 1 illustrates a front view of a VFD apparatus in accordance with the embodiments of this disclosure.

FIG. 2 illustrates a side view of the VFD apparatus in accordance with the embodiments of this disclosure.

FIG. 3 illustrates a top view of the VFD apparatus in accordance with the embodiments of this disclosure.

FIG. 4 illustrates a block-diagram of the VFD in accordance with the embodiments of this disclosure.

### DETAILED DESCRIPTION OF INVENTION

The following detailed description is presented to enable any person skilled in the art to make and use the invention. For purposes of explanation, specific details are set forth to provide a thorough understanding of the present invention. However, it will be apparent to one skilled in the art that these specific details are not required to practice the invention. Descriptions of specific applications are provided only as representative examples. Various modifications to the preferred embodiments will be readily apparent to one skilled in the art, and the general principles defined herein may be applied to other embodiments and applications without departing from the scope of the invention. The present invention is not intended to be limited to the embodiments shown but is to be accorded the widest possible scope consistent with the principles and features disclosed herein.

For the purposes of easier understanding, the terms “panel” and “enclosure” are interchangeably used in this disclosure to describe a housing of a VFD that encloses all the internal parts of the VFD. Further, internal electronic components may not necessarily be limited to the components disclosed explicitly in this disclosure and may include any electronic component that may be required for the functioning of the VFD in accordance with the disclosed embodiments. Further, the VCT disclosed in the following embodiments may not necessarily be of the same shape, size and cross-section as illustrated in the corresponding figures and may have any shape such as, but not limited to, spherical, cylindrical, cuboidal that may be either geometrically symmetrical or asymmetrical without departing from the scope of the ongoing description. Further, the VCT may be partially or completely hollow or in some embodiments, may not be hollow at all but still is capable of being designed in a manner so as to isolate the internal circuitry from the air that enters the VCT. In addition, the terms, “VFD”, “VFD package”, and “VFD apparatus” are used interchangeably throughout the disclosure. Additionally, the exhaust mechanism may comprise fans, slits, or vents or any other equivalent arrangement to expel air out of the VFD without departing from the scope of the ongoing disclosure.

Below is an explanation of sample calculations required for adequate ventilation/cooling of VFDs. These calculations are described for illustration purposes and do not take into consideration, external factors, such as direct sunlight or additional heat sources.

The first step in heat management is to calculate how much heat the VFD equipment generates. This is dependent on the type of equipment and how it is configured and operated. To calculate VFD Heat Dissipation, the thermal losses of the VFD may, for all practical purposes, be assumed to be about 3%. The thermal losses for smaller VFDs may be assumed to be approximately 4% and as the size of the VFD increases, the percentage of thermal losses decreases to about 3%. For the purposes of below explanations, the above general rules are considered.

In an exemplary scenario, the estimated heat generated by a 40 Ampere VFD controlling a 22 Kilowatt electric motor at full load is:
P_{LOSS}=22 kW×0.03
=0.66 kW
=660 W

Another consideration in these calculations may be the auxiliary equipment. Where additional equipment is mounted in the same enclosure as the VFD, any heat generated by such auxiliary equipment must be added to the total heat generated. Equipment suppliers may provide details of the heat generated by their equipment(s).

Further, various installation alternatives may also need to be considered. VFDs are available in different types of enclosures like most electrical equipment to suit the environment in which they need to be installed. The type of enclosure supplied is based on the level of protection offered against water and objects, known as an Ingress Protection (IP) rating. If the protection offered is not adequate for the environment to be installed, then other alternatives need to be investigated.

One alternative is to use a VFD with a higher IP rating. Some VFDs are available in IP30, IP66 and also Stainless Steel IP66 rating, which implies that they may be installed without further protection. However, the disadvantages of doing so are that the power range and feature availability are very limited in these model drives. This limits the application to only a small subset of requirements.

Yet another alternative is to relocate the VFD to an alternative location/position. However, such relocation may not always be a feasible option given certain design constraints.

Yet another alternative is to install the VFD equipment in an enclosure with a higher IP rating. The disadvantage with this alternative is that when the VFD equipment (that generates heat) is installed into another enclosure, the heat must still be dissipated. If this heat is not removed, the heat inside the VFD will build up to a level which will affect the reliable operation of the equipment, reduce the life expectancy of the product, and/or cause failure to other equipment(s). If it is chosen to ventilate the enclosure, this may reduce the IP rating to an unacceptable level.

An additional alternative is to use a “push through” design. This is a popular alternative which locates the heat sinks outside the enclosure envelope and therefore isolates the heat from the sensitive controls. This gives the overall assembly a higher thermal rating, implying that the VFD can survive in higher ambient climates. However, a disadvantage of this design is exposure of the cooling fans and heat sink to the environment, which may cause premature fan failure or degraded heat dissipation, thereby, causing premature faults and ultimately, failure of the drive (i.e., VFD).

An additional consideration may be VFD enclosure dissipation or ventilation. The dimensions of the enclosure, how it is mounted, and the outside ambient temperature defines the amount of heat that can be dissipated through the exposed surfaces of the enclosure. In scenarios where the surface area of the enclosure is insufficient to dissipate the heat generated inside the enclosure, the remaining/residual heat may be removed by forced ventilation.

The heat generated within the enclosure may be dissipated by one or more methods as described below. Non-ventilated enclosures rely on the heat being dissipated through the walls of the enclosure. The better heat conduction of the enclosure leads to more dissipation of heat. Therefore, metal enclosures are better at dissipating heat than plastic enclosures.

The power that can be dissipated in a given exposed surface area is given by the expression below:

P_{ESA}=k×S×ΔT, where:
P_{ESA}: Power dissipated from within the enclosure via exposed surface area in Watts (W)
k: Heat transfer coefficient (sheet metal˜5.5 W/m2K, plastic˜3.5 W/m2K)
S: Corrected enclosure surface area of the enclosure, in m² in accordance with IEC890.
ΔT: Temperature differential (inside enclosure−outside ambient), in ° C.

However, with a ventilated enclosure, the heat is dissipated by forcing ambient air in or out of the enclosure. The objective here is to circulate the air through the enclosure. Therefore, it may not be critical whether the fan creates a pressure or vacuum in the enclosure (that is, blows in or out). Generally, ambient air is drawn in at the bottom of the cabinet and discharged through a ventilation opening at the top. Therefore, the outlet should be placed above the highest mounted VFD.

Filters installed on fan units provide a better IP rating (e.g., IP54) but impede the flow of air. It is important to check the manufacturer's specifications when a filter is fitted. Additionally, if the filter collects any dust, the airflow may be reduced significantly and may need to be considered in the selection decision and design.

The volume of air required may be estimated using the formula:

V=(3.1×P_{EXHAUST})/ΔT, where—
V: Volume of air flow required, in m3/hr
P_{EXHAUST}: Power exhausted from within the enclosure, in W
ΔT: Temperature differential (inside enclosure−outside ambient), in ° C.

One popular method for heat mitigation is to use a push through design, which is a design provided by the drive manufacturer to locate the heat sinks on the outside of the panel by cutting an opening and sealing that opening with an adapter made for this purpose. This method may have several disadvantages. For instance, placing the heatsinks in the weather exposes the fans to the weather, and thus, reduces their life cycle considerably. In addition, heat sinks exposed to the ambient environment can be contaminated, and thus reduce their performance. Furthermore, the exposed heat sinks are usually protected with a shroud. This adds costs and additional size and is not particularly effective in protecting the heatsink or the cooling fans.

Further, there may be additional considerations in the design and selection of best method/system as described below:

Equipment Spacing—To adequately exhaust the generated heat, certain minimum clearances must be maintained around the VFD. The VFD installation manual may be referred for details on specification of the VFD.

Equipment/Stirring fans—Stirring fans distribute the heat evenly throughout the enclosure to avoid hot spots. Fans may be controlled to run for a given time at starting or temperature may be controlled to extend fan life and reduce audible noise.

Forced Ventilation—Where ventilation is used to exhaust heat, care should be taken with regard to IP rating of the enclosure. Furthermore, the size of the air intake should be at least the size of the exit and if more than one fan is used then the fans should be the same. Where filters are used, pressure drops across the filters should be taken into consideration. Filters should be inspected regularly for blockage as part of the maintenance schedule to ensure free air flow and correct operation. Force ventilation may also be temperature controlled to minimize running time and increase the life expectancy of the fans.

Equipment Derating—The components of electronic equipment are designed to operate under full load at a particular maximum temperature. By reducing the load, the internal operating temperature may be reduced allowing the equipment to operate in a higher ambient temperature. The instruction manual or the local representative may be referred to for manufacture derating. Derating can significantly increase the cost of the overall product.

Solar Heating—Exposure of the enclosure to the sunlight (direct or reflected) may result in solar heating. Proper use of a shelter may reduce such heating. The enclosure material and paint colors have different absorption properties of solar energy. Traditional VFD packages and bare VFD chassis should not be mounted in direct sunlight or on hot surfaces.

Environment—The environment of a VFD installation determines the type of enclosure to be used. In an example scenario where dust and water (or moisture) are present, one may consider using an IP66 enclosure which would then rely entirely on radiated heat loss for cooling or a heat exchanger will be needed. For aggressive environments one may use a stainless steel or plastic enclosure. If a fan or fan/filter is installed, the IP66 rating will be degraded.

In view of the above described challenges, the present disclosure proposes various embodiments of a variable frequency drive (VFD) apparatus. In an embodiment, the VFD apparatus includes an enclosure and one or more internal components housed in a first portion of the enclosure. Further, the VFD apparatus includes a compartment housed in a second portion of the enclosure. In an embodiment, the compartment includes an ingress for facilitating entry of air into the compartment and an egress for facilitating an exit of the entered air from the compartment. The first portion of the enclosure is isolated from the second portion of the enclosure.

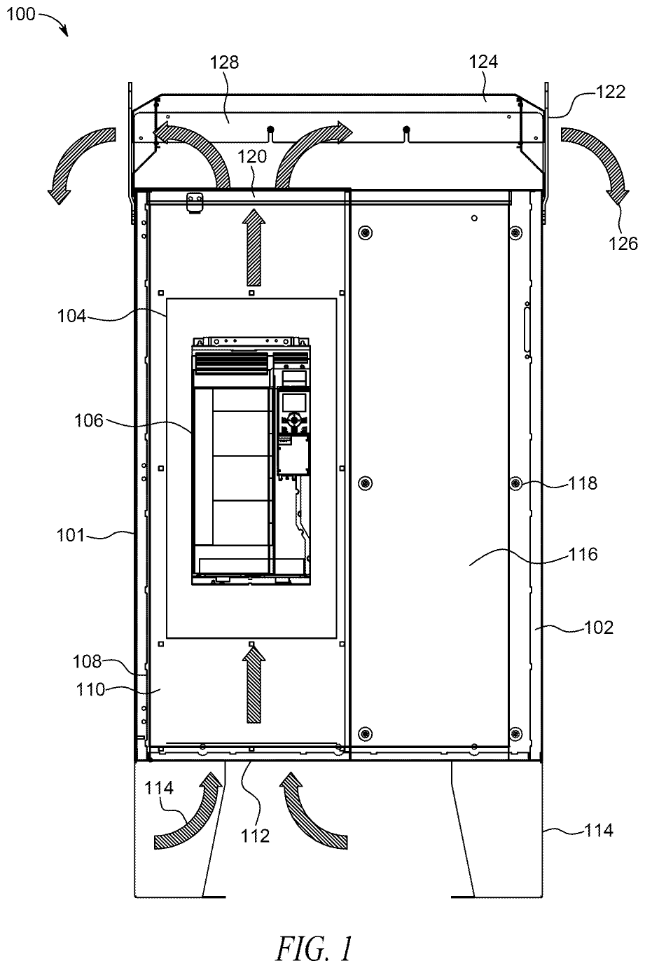

FIG. 1 illustrates a front view 100 of a VFD apparatus 101 in accordance with the embodiments of this disclosure. The VFD apparatus 101 comprises an enclosure 102, a first portion 104, and a second portion 108. The first portion 104 comprises one or more internal electronic components 106 that are essential for the functioning of the VFD apparatus 101. These components 106 may include various electronic components such as, but not limited to, diodes, transistors, capacitors, resistors in any suitable combination depending on the design requirements of the VFD apparatus 101.

Further, the second portion 108 of the enclosure 102 may comprise a compartment 110 for facilitating flow of air for cooling the VFD in accordance with the embodiments of this disclosure. For instance, the compartment 110 may be a Vortex Cooling Tunnel (VCT) inside the enclosure 102 that isolates, the heat generated from the watt loss from, the other internal components 106 of the enclosure 102. The cooling tunnel has been referred to as “Vortex” Cooling Tunnel because the airflow through the tunnel is achieved/facilitated in a manner similar to a vortex region as understood in the context of fluid dynamics. For instance, the airflow velocity may be greatest next to an axis (of the cooling tunnel) and may decreases in inverse proportion to the distance from the axis. For instance, the distribution of velocity, vorticity (the curl of the flow velocity), as well as the concept of circulation may be used to characterize the airflow through the cooling tunnel. However, the mere naming convention does not restrict any design changes to the VFD/VCT, that may be made according to the implementation requirements. It may be appreciated that various shapes, sizes, dimensions, and cross sections are envisaged which may or may not lead to vortex-like characteristics in the airflow through the cooling tunnel without departing from the scope of the ongoing disclosure.

Further, the structure of the VCT in the enclosure 102 is such that the first portion 104 housing the one or more internal electronic components 106 is isolated from the second portion 108 that houses the VCT (i.e., the compartment 110). This prevents the external air that enters the VCT through an ingress 112 of the compartment 110, from flowing through the isolated first portion 104 of the enclosure 102, thereby, protecting the components 106 from contaminants that may be present in the air.

The shape of the VCT may be a symmetrical geometric shape such as, but not limited to, a cuboidal, or a cylindrical shape. The cross-section of the VCT may accordingly be circular, square, or rectangular or any other shape depending on the overall dimensions of the VCT. In some embodiments, the dimensions of the VCT may be varied within the design constraints of the VFD. In one exemplary scenario, the dimensions of the VFD may be 60×36×24 (length×width×height) inches. The dimensions of the VCT may accordingly be varied to accommodate the VCT within the VFD based on design considerations as described above. For example, one half of the volume available within the VFD may be designated for a cuboidal VCT having dimensions 30×18×12 inches. In this example, the VCT may also house the internal circuitry and internal electronic components of the VFD while maintaining isolation from the air entering the VCT. In another example, the VCT may be cylinder with a diameter of 12 inches and a height/length of 30 inches. The remaining volume, in both these examples, inside the VFD may be used for other components such as, but not limited to, the exhaust mechanism and heat sinks.

In some embodiments, the VCT may be rated as National Electrical Manufacturers Association (NEMA) 3R or NEMA 3RX. The section of the enclosure 102 (e.g., first portion 104) that is isolated from the VCT may be rated as NEMA 3R, NEMA 3RX, NEMA 4, NEMA 4X or NEMA 12. Herein, the terms “enclosure 102” and “panel” are used interchangeably throughout the disclosure for ease of explanation and understanding.

In some embodiments, the VCT (compartment 110) may comprise the ingress 112 through which external air enters the VCT. The air flowing 114 into the VCT may comprise one or more foreign objects such as, but not limited to, dirt particles, moisture, insects and so on. According to the embodiments of the present disclosure, such objects are restricted from entering internal electronic components 106 and any associated circuitry of these components 106. This objective is achieved by isolating the VCT from the portion of the enclosure 102 that houses these internal electronic components 106 and any associated circuitry.

According to the embodiments, the need for an air conditioner may also be eliminated by isolating the heat that is generated from the watt loss from the other components 106 of the panel. This eliminates outside air from flowing through the isolated portion of the panel protecting the components 106 from contaminants. The VCT may be rated as NEMA 3R or NEMA 3RX. The section of the panel that is isolated from the VCT may be rated as NEMA 3R, NEMA 3RX, NEMA 4, NEMA 4X or NEMA 12.

One of the design features of the enclosure presented in this disclosure is that it enables the VFD to cool itself by dissipating heat. Using external blowers may have several disadvantages:
a. the mean time between failure (MTBF) for the drive package is greatly reduced due to fan failure times;
b. opening holes for ventilation caused issues with the Underwriters Laboratories (UL) 508 standard conformity and most often reduces the desired IP rating;
c. push or pull fan configurations require filters which reduces the resulting air flows and degrades fan performance and lifecycle; and
d. bringing outside air into the enclosure invites contamination.

The present disclosure, therefore, proposes to develop a tunnel (e.g., the VCT) inside the above-described enclosure that allows air flow over one or more VFD heat sinks 128 of the VFD apparatus 101. This method isolates the heat and outside air from the inside of the enclosure and critical electronic components 106. This upgrades the environmental rating and extends the life of the VFD package improving the overall reliability in the process. Here, the terms, “VFD”, “VFD package”, and “VFD apparatus” are used interchangeably throughout the disclosure.

Further, for additional stability, the VFD enclosure 102 may comprise an enclosure stand 114 that may include two or more legs to support the VFD. The enclosure may further comprise an outer covering 116 that is attached to the enclosure 102 by means of fixtures 118 which may comprise screws, nuts and bolts, or adhesives. The outer covering 116 may provide additional safety from external shocks or environmental factors.

Further, once the air 114 enters the second portion 108, it flows through the compartment 110 in such a manner that the design of the VCT isolates it from entering the first portion 104 and damaging the internal electronic components 106. The air then traverses through the VCT housed in the second portion 108 and the heat generated from the internal components 106 during their operation is dissipated into the air traversing through the VCT. Thus, the heat is not allowed to damage the components 106. The heated air then exits the compartment 110 from an egress 120 and flows over one or more heat sinks 128 in the enclosure 102. In one example, where the dimensions the VCT are 30×18×12 inches, the heat sinks 128 may be located at a predetermined distance that is close enough to the VCT egress 112 to absorb as much heat as possible. In this example, the distance may be 2 inches from the egress of the VCT. Subsequently, an exhaust mechanism 122 in the enclosure 102 facilitates the exit of the air flowing through the heat sinks 128, out of the enclosure 102. The exit air flow 126 is shown in FIG. 1. In one example, the distance of the exhaust mechanism may be 2 inches from the heat sinks 128. However, this distance can vary depending on design requirements.

The exhaust mechanism 122 may be installed in a hood 124 of the enclosure 102. In some embodiments, the exhaust mechanism 122 may be installed on the sides of the hood 124 while in some other embodiments, it may be installed on the top of the hood 124. The exhaust mechanism 122 may comprise one or more exhaust fans, slits, or an equivalent arrangement suitable to push hot air flowing over the heat sinks outside of the VFD.

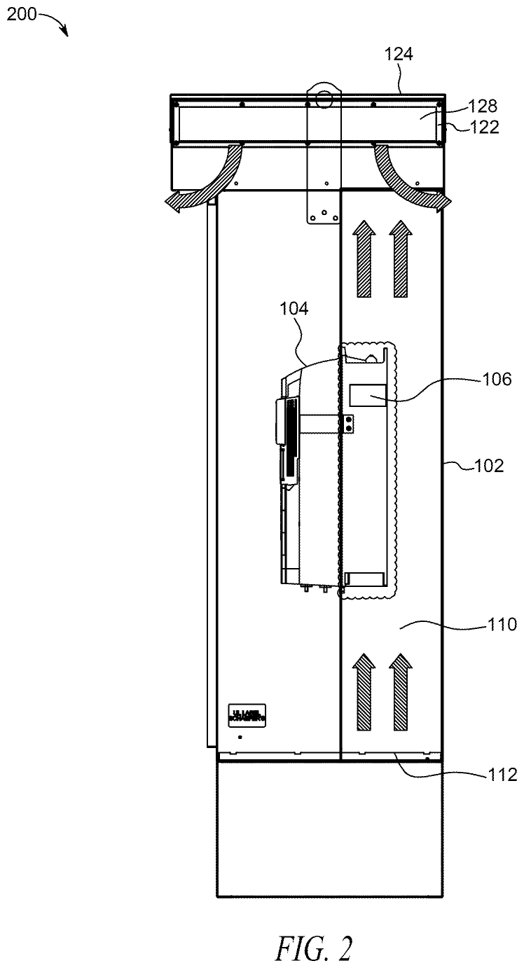

FIG. 2 illustrates a side view 200 of the VFD apparatus 101, in accordance with the embodiments of this disclosure. Since the first portion 104 of the enclosure 102 (comprising the electronic components 106 and circuitry) is isolated from the second portion 108 (that comprises the VCT or the compartment 110), the air that enters the VCT does not come in contact with the electronic components 106. The air passes through the VCT to flow over one or more heat sinks 128 that may be included in the enclosure 102 and subsequently, exits the enclosure 102 through an exhaust mechanism 122 in the enclosure 102. The disclosure does not limit the placement of the exhaust mechanism 122 in any manner. In one exemplary instance, the exhaust mechanism 122 may comprise exhaust fans, slits, or vents that may be located on a hood (top) 124 of the enclosure while in another exemplary instance, the exhaust mechanism 122 may be located on one or more sides of the enclosure 102. The location of the exhaust mechanism 122 on the sides of the enclosure may ensure better safety for a user.

In accordance with the embodiments of the disclosure, a prototype was prepared and commercially named as “advanced tunnel design”. On testing the prototype, the following observations were concluded:
a) the shape and size of the tunnel make a significant difference in performance;
b) the construction of the tunnel was modified as described above to assist easing of routine maintenance;
c) the size and shape of the ingress is critical—not only to incoming air flow, but ingress of insects and other foreign objects as well; and
d) the placement of the intake/ingress is critical to optimize performance.

In view of the above observations, modifications were made to both the intake as described above and the exhaust mechanism, compared to the conventional solutions available. For instance, in one scenario, the exhaust mechanism may be placed on top front of the enclosure 102. However, in another scenario, in order to improve air flow, and more importantly—for better safety, placing the exhaust mechanism 122 on the sides of the hood 124 is a better option. Similarly, the position of the ingress 112 may be predetermined by the manufacturer and is not limited by the present disclosure. The ingress 112 may be located either on one or more sides of the enclosure 102 or the top (hood) 124 of the enclosure 102 depending on the design requirements and safety considerations. Additionally, the shape and size of the ingress 112 may be predetermined such that it is optimal to facilitate the inflow of air but restricts the inflow of insects or foreign contaminants. In one example the shape of the ingress 112 may be circular and the diameter may be one-fourth of an inch. Additionally, a sieve may be installed on the ingress 112 to restrict the flow of contaminants into the VCT. On the contrary, the egress 120 may be relatively wider in diameter (for example, 1 inch) to expel maximum air to the heat sinks 128.

For the purposes of providing commercial relevance, several prototypes have been prepared and tested for the invention disclosed here. The results obtained from the testing have been satisfactory and indicative of the fact that the implementation in conducive for mass-production. The prototypes have been tested, both in a controlled environment as well as in a production setting with satisfactory results. The above prototypes include modifications to the hood, access plates, mounting adapters, tunnel shape and size, and intake design, as described above.

Further, the shape and size of the VCT (tunnel) may be adapted to the characteristics of the VFD installed, as described above. In one example, the shape of the VCT may be cylindrical and the cross-sectional diameter may be 12 inches with a height of 30 inches. Further, the tunnel shape and size can be so designed such that the first and the second portions as described above are isolated and the air entering the compartment 110 does not enter and damage the internal electronic components 106 of the first portion 104. In some embodiments, the shape and size of the compartment 110 may be predetermined depending on the design requirements and to achieve the objective of isolating the first and the second portions of the VFD package. In yet another example, the shape of the VCT may be conical with the diameter decreasing along the axis from one end to the other.

Further, in an embodiment of the invention, the access plates provide access to the cooling fans and heatsinks of the VFD. Furthermore, mounting adapters may be used to mount the VFD on an external periphery or a device such as an electronic motor. In one example, the above-described design modifications may be such that the VFD is able to achieve a variable torque, a voltage rating range of 240-480 volts, a horsepower of 200 HP and an Ampere rating of 250 Amperes. In another example, the horsepower range may be 1-700 HP with other parameters remaining the same. While the overall dimensions of the VFD in these examples may vary greatly, an exemplary embodiment of this example may be 60×36×24 inches.

The prototyped design performs satisfactorily and is simple enough to be released for mass production. The advantages of the proposed embodiments and designs include elimination/prevention of outside air from flowing through the isolated portion of the enclosure 102 protecting the components 106 from contaminants. In addition, the space required inside the enclosure 102 to sufficiently cool the VFD is reduced and the VCT results in more efficient cooling of the VFD.

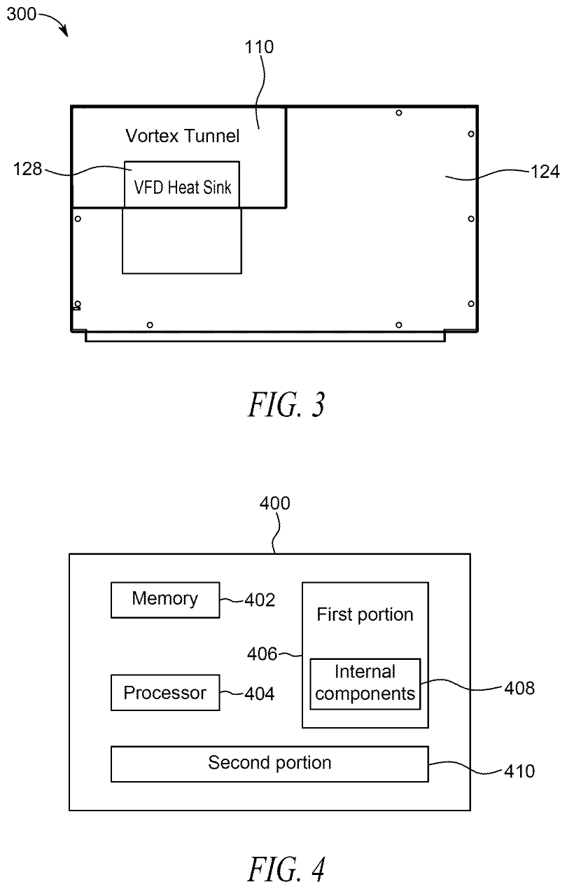

FIG. 3 illustrates a top view 300 of the VFD apparatus 101 in accordance with the embodiments of this disclosure. This figure illustrates the top view 300 of the VCT, which allows the external air to traverse the compartment 110, that is, the VCT or vortex tunnel and subsequently, flow over the VFD heat sink 128, thus, provide a cooling mechanism to the VFD. The air then, exits through the exhaust mechanism (shown in FIG. 1) provided in the hood 124 of the enclosure.

FIG. 4 shows a basic illustration of a VFD 400 as discussed above in accordance with the embodiments of this disclosure. The VFD package is equivalent the VFD described in detail in the context of FIGS. 1-3. The VFD 400 may comprise a memory 402 that comprises computer-executable instructions that when executed, cause the processor 404 to facilitate an inflow of external air, into a compartment housed in a second portion 410 (or second portion 108) of an enclosure of the VFD 400. The instructions further cause the processor 404 to traverse the entered air through the compartment to facilitate an exit of the air through an egress, wherein the traversed air is isolated from one or more internal components 408 (or internal components 106) housed in a first portion 406 (or first portion 104) of the enclosure. Further, the instructions cause the processor 404 to facilitate the flow of the exited air over one or more heat sinks housed in the enclosure and subsequently, facilitate the exit of the air flowing through the one or more heat sinks through an exhaust mechanism.

Additionally, the VFD may include an in-built microcontroller. An embedded microprocessor may govern the overall operation of the VFD controller. Basic programming of the microprocessor may be provided as user-inaccessible firmware. User programming of display, variable, and function block parameters may be provided to control, protect, and monitor components of the VFD (e.g., motor, the driven equipment).

In further accordance with the embodiments of this disclosure, a method for cooling the VFD, is disclosed herein. The method comprises facilitating an inflow of air, through an ingress, into a compartment (e.g., the VCT) housed in a second portion of an enclosure of the VFD. The method further comprises traversing the entered air through the compartment to facilitate an exit of the air through an egress; wherein the traversed air is isolated from one or more internal components housed in a first portion of the enclosure. The method further comprises facilitating the flow of the exited air over one or more heat sinks housed in the enclosure and subsequently, facilitating the exit of the air flowing through the one or more heat sinks through an exhaust mechanism

The terms “comprising,” “including,” and “having,” as used in the claims and specification herein, shall be considered as indicating an open group that may include other elements not specified. The terms “a,” “an,” and the singular forms of words shall be taken to include the plural form of the same words, such that the terms mean that one or more of something is provided. The term “one” or “single” may be used to indicate that one and only one of something is intended. Similarly, other specific integer values, such as “two,” may be used when a specific number of things is intended. The terms “preferably,” “preferred,” “prefer,” “optionally,” “may,” and similar terms are used to indicate that an item, condition, or step being referred to is an optional (not required) feature of the invention.

The invention has been described with reference to various specific and preferred embodiments and techniques. However, it should be understood that many variations and modifications may be made while remaining within the spirit and scope of the invention. It will be apparent to one of ordinary skill in the art that methods, devices, device elements, materials, procedures, and techniques other than those specifically described herein can be applied to the practice of the invention as broadly disclosed herein without resort to undue experimentation. All art-known functional equivalents of methods, devices, device elements, materials, procedures, and techniques described herein are intended to be encompassed by this invention. Whenever a range is disclosed, all subranges and individual values are intended to be encompassed. This invention is not to be limited by the embodiments disclosed, including any shown in the drawings or exemplified in the specification, which are given by way of example and not of limitation.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

All references throughout this application, for example patent documents including issued or granted patents or equivalents, patent application publications, and non-patent literature documents or other source material, are hereby incorporated by reference herein in their entireties, as though individually incorporated by reference, to the extent each reference is at least partially not inconsistent with the disclosure in the present application (for example, a reference that is partially inconsistent is incorporated by reference except for the partially inconsistent portion of the reference).

We hereby claim:

1. A variable frequency drive (VFD) apparatus, comprising:
an enclosure;
one or more internal components housed in a first portion of the enclosure; and
a compartment housed in a second portion of the enclosure, wherein the compartment comprises an ingress for facilitating entry of air into the compartment and an egress for facilitating an exit of the entered air from the compartment,
wherein the first portion of the enclosure is isolated from the second portion of the enclosure.

2. The apparatus of claim 1, wherein the compartment is a vortex cooling tunnel.

3. The apparatus of claim 1, wherein the compartment isolates, air flowing through the compartment, from the one or more internal components housed in the first portion.

4. The apparatus of claim 1, wherein the compartment has an ingress protection (IP) rating comprising one of National Electrical Manufacturers Association (NEMA) 3R and NEMA 3RX.

5. The apparatus of claim 1, wherein the second portion has an IP rating comprising one of NEMA 3R, NEMA 3RX, NEMA 4, NEMA 4X and NEMA 12.

6. The apparatus of claim 1, wherein the air flowing through the compartment includes one or more foreign objects.

7. The apparatus of claim 1, further comprising one or more heat sinks disposed in such a manner that the exited air flows over the one or more heat sinks.

8. The apparatus of claim 1, wherein the compartment has a predetermined shape and size.

9. The apparatus of claim 1, wherein the ingress has a predetermined shape and size.

10. The apparatus of claim 1, wherein a placement of the ingress is predetermined.

11. The apparatus of claim 10, wherein the ingress is placed at one of: a bottom of the enclosure or on one or more sides of the enclosure.

12. The apparatus of claim 7 further comprising an exhaust mechanism associated with the egress, placed on one or more sides of a hood of the enclosure, and wherein the exhaust mechanism facilitates an exit of the air flowing over the one or more heat sinks.

13. The apparatus of claim 1, further comprising an enclosure stand to support the enclosure.

14. A method of cooling a variable frequency drive (VFD), the method comprising:
facilitating an inflow of air, through an ingress, into a compartment housed in a second portion of an enclosure of the VFD;
traversing the entered air through the compartment to facilitate an exit of the air through an egress, wherein the traversed air is isolated from one or more internal components housed in a first portion of the enclosure;
facilitating the flow of the exited air over one or more heat sinks housed in the enclosure; and
facilitating the exit of the air flowing through the one or more heat sinks through an exhaust mechanism.
